(19) United States
(12) Patent Application Publication
(10) Pub. No.: US 2016/0272779 A1
(43) Pub. Date: Sep. 22, 2016

(54) FLAME RETARDANT LED FOR INDOOR LIGHTING

(71) Applicant: SOLVAY SPECIALTY POLYMERS USA, LLC, Alpharetta, GA (US)

(72) Inventors: Alessandro BONGIOVANNI, ALPHARETTA, GA (US); Charles RONEY, Duluth, GA (US); Glenn CUPTA, Roswell, GA (US)

(73) Assignee: SOLVAY SPECIALTY POLYMERS USA, LLC, Alpharetta, GA (US)

(21) Appl. No.: 15/034,108

(22) PCT Filed: Nov. 3, 2014
(86) PCT No.: PCT/EP2014/073586

§ 371 Date: May 3, 2016

Related U.S. Application Data
(60) Provisional application No. 61/900,670, filed on Nov. 6, 2013.

(51) Int. Cl. C08K 3/22; C08K 7/14; C08L 67/02; C08K 3/34; C08K 5/5313; C08L 77/06; H01L 33/60; C08K 5/3435

(52) U.S. Cl. CPC C08K 3/22; H01L 33/60; C08K 7/14; C08K 5/3435; C08K 3/34; C08K 5/5313; C08L 77/06; C08L 67/02; C08K 2003/222; C08K 2003/2241; C08L 2201/02; C08L 2203/20; C08L 2205/03; C08L 2205/06; C08L 2207/04; C08L 2207/066

(57) ABSTRACT

The present invention relates to Light Emitting Diode (LED) devices featuring outstanding reflectivity and flame resistance. The LED according to the present invention comprises at least a part comprising a polymer composition (C) comprising at least one polymer (P) selected from the group consisting of a polyamide, a polyester, an epoxy and a silicon resin; a flame retardant and magnesium oxide.

This application claims priority to U.S. provisional application No. 61/900,670 filed Nov. 6, 2013, the whole content of this application being incorporated herein by reference for all purposes.

### FIELD OF THE INVENTION

The present invention relates to flame retardant Light Emitting Diode devices (LED) and more particularly to LED's made from a polymer composition (C) comprising at least one polymer selected from the group consisting of a polyamide, a polyester, an epoxy and a silicon resin, a flame retardant system and magnesium oxide.

### BACKGROUND OF THE INVENTION

The first LED's were introduced in the late 1990s. Since then, the unit costs have been steadily declining by double-digit percentages, making LED lighting technology viable for commercial, industrial and outdoor lighting applications. Huge strides have also been made in improving the efficiency, lumen output and performance of LED lights. These massive improvements in

LED's lead to the fact that LED's are currently replacing incandescent and fluorescent bulbs in housing and commercial markets. Last but not least, reduction in CO₂ emissions by going to LED alternatives is also a key driving factor near and dear to government environmental agencies, pushing the LED market growth a step further.

The growing use of LED's for indoor lighting applications is leading to a new requirement for thermoplastic compound formulations used for their manufacture to impart flame retardancy in addition to performance characteristics including electrical conductivity, electrical insulativity, processability, reflectance retention after heat and/or light exposure and mechanical strength.

Flame retardant chemicals can be introduced into thermoplastic compounds to improve their flammability ratings. Introducing flame retardants into thermoplastic compounds helps impart ignition resistance and inhibits or resists the spread of fire. This added property allows for thermoplastic compounds to be utilized safely where a potential for fire exists, meeting the requirements of Underwriter Labs UL-94 and the International Electrotechnical Commission (IEC).

However, Applicant has discovered that the simple addition of common flame retardant chemicals into thermoplastic compounds does not result in the production of compounds suitable for the manufacture of LED's and in particular for the manufacture of LED reflectors. It appeared very difficult to obtain a compound featuring flame resistance and high light reflectance at the same time.

US 2010/270577 relates to polyamide compounds suitable for the manufacture of plastic components for use in a lighting system such as a LED. US'577 discloses the possibility of adding a flame retardant system to the compound which may comprise a halogenated flame retardant and/or a halogen free flame retardant, and next it an optional a flame retardant synergist. US'577 only discloses and exemplifies a brominated polystyrene as flame retardant and zinc borate as synergist. Interestingly, US'577 does not disclose neither the flame resistance nor the reflectance performance of the compounds exemplified.

US 2013/0094207 discloses certain flame retarded polyamide compositions in its examples 26 to 30, but once again fail to report the whiteness and/or reflectance data of these compounds.

The ones skilled in the art of flame retarded polymer composition know for a fact that about at least 10 wt. % of flame retardant chemicals are necessary to improve the overall flame retardancy of the polymer compositions. It is challenging to maintain the high level of properties of compounds fulfilling the very strict requirements for the LED market while replacing 10 wt. % of those compositions by flame retardant chemicals.

There is thus a need in the art for white flame retarded polymer compositions featuring high reflectance of light, high dimensional stability, high mechanical strength, high heat deflection temperature and high heat resistance while being easily processed into the desired shaped, suitable for the manufacture of LED components such as LED reflectors.

The Applicant has surprisingly found that the incorporation of magnesium oxide into these prior art thermoplastic compositions surprisingly reduce the flammability of the composition while substantially maintaining the high level of mechanical properties (notably, high dimensional stability and high mechanical strength), the good processability and light reflectance of the composition.

### SUMMARY OF THE INVENTION

The present invention relates to a part of a Light Emitting Diode device comprising a polymer composition (C) comprising:
at least one polymer (P) selected from the group consisting of a polyamide, a polyester, an epoxy and a silicon resin;
from 5 to 40 wt. %, based on the total weight of the composition (C), of a flame retardant system ;
from 1 to 7 wt. %, based on the total weight of the composition (C), of magnesium oxide.

### DETAILED DESCRIPTION OF THE INVENTION

The polymer composition (C) of the present invention comprises three essential ingredients that are described in detail here below:

### The Polymer (P)

The polymer composition (C) of the present invention comprises at least one polymer (P) selected from the group consisting of a polyamide, a polyester, an epoxy and a silicon resin.

In certain embodiments, the polymer (P) is preferably a polyamide. The expression “polyamide” is intended to denote any polymer which comprises recurring units (R_{PA}) which are derived from the polycondensation of at least one dicarboxylic acid component (or derivative thereof) and at least one diamine component, and/or from the polycondensation of aminocarboxylic acids and/or lactams.

The expression “derivative thereof” when used in combination with the expression “carboxylic acid” is intended to denote whichever derivative which is susceptible of reacting in polycondensation conditions to yield an amide bond. Examples of amide-forming derivatives include a mono- or di-alkyl ester, such as a mono- or di-methyl, ethyl or propyl ester, of such carboxylic acid; a mono- or di-aryl ester thereof; a mono- or di-acid halide thereof; and a mono-or di-acid amide thereof, a mono- or di-carboxylate salt.

In certain preferred embodiment, the polyamide of the polymer composition (C) comprises at least 50 mol %, preferably at least 60 mol %, more preferably at least 70 mol %, still more preferably at least 80 mol % and most preferably at least 90 mol % of recurring units (R_{PA}). Excellent results were obtained when the polyamide of the polymer composition (C) consisted of recurring units (R_{PA}).

The nature and quantities of the dicarboxylic acid component, the diamine component, and/or the aminocarboxylic acids and/or lactams has a great impact on the amorphous or semi-crystalline behaviour of the overall polyamide.

The polyamide of the polymer composition (C) is preferably an aromatic polyamide polymer. For the purpose of the present invention, the expression “aromatic polyamide polymer” is intended to denote a polyamide which comprises more than 35 mol %, preferably more than 45 mol %, more preferably more than 55 mol %, still more preferably more than 65 mol % and most preferably more than 75 mol % of recurring units (R_{PA}) which are aromatic recurring units. For the purpose of the present invention, the expression “aromatic recurring unit” is intended to denote any recurring unit that comprises at least one aromatic group. The aromatic recurring units may be formed by the polycondensation of at least one aromatic dicarboxylic acid with an aliphatic diamine or by the polycondensation of at least one aliphatic dicarboxylic acid with an aromatic diamine, or by the polycondensation of aromatic aminocarboxylic acids. For the purpose of the present invention, a dicarboxylic acid or a diamine is considered as “aromatic” when it comprises one or more than one aromatic group.

Non limitative examples of aromatic dicarboxylic acids are notably phthalic acids, including isophthalic acid (IA), terephthalic acid (TA) and orthophthalic acid (OA), 2,5-pyridinedicarboxylic acid, 2,4-pyridinedicarboxylic acid, 3,5-pyridinedicarboxylic acid, 2,2-bis(4-carboxyphenyl)propane, bis(4-carboxyphenyl)methane, 2,2-bis(4-carboxyphenyl)hexafluoropropane, 2,2-bis(4-carboxyphenyl)ketone, 4,4′-bis(4-carboxyphenyl)sulfone, 2,2-bis(3-carboxyphenyl)propane, bis(3-carboxyphenyl)methane, 2,2-bis(3-carboxyphenyl)hexafluoropropane, 2,2-bis(3-carboxyphenyl)ketone, bis(3-carboxyphenoxy)benzene, the 2,6-naphthalene dicarboxylic acid, 2,7-naphthalene dicarboxylic acid,1,4-naphthalene dicarboxylic acid, 2,3-naphthalene dicarboxylic acid, 1,8-naphthalene dicarboxylic acid, 1,2-naphthalene dicarboxylic acid.

Among aliphatic dicarboxylic acids, mention can be notably made of oxalic acid [HOOC—COOH, malonic acid (HOOC—CH₂—COOH), adipic acid [HOOC—(CH₂)₄—COOH], succinic acid [HOOC—(CH₂)₂—COOH], glutaric acid [HOOC—(CH₂)₃—COOH], 2,2-dimethyl-glutaric acid [HOOC—C(CH₃)₂—(CH₂)₂—COOH], 2,4,4-trimethyl-adipic acid [HOOC—CH(CH₃)—CH₂—C(CH₃)₂—CH₂—COOH], pimelic acid [HOOC—(CH₂)₅₋COOH], suberic acid [HOOC—(CH₂)₆—COOH], azelaic acid [HOOC—(CH₂)₇—COOH], sebacic acid [HOOC—(CH₂)₈—COOH], undecanedioic acid [HOOC—(CH₂)₉—COOH], dodecanedioic acid [HOOC—(CH₂)₁₀—COOH], tetradecanedioic acid [HOOC—(CH₂)₁₁—COOH], cis- and/or trans-cyclohexane-1,4-dicarboxylic acid and/or cis- and/or trans-cyclohexane-1,3-dicarboxylic acid.

According to preferred embodiments of the present invention, the dicarboxylic acid is preferably aromatic and comprises advantageously at least one phthalic acid selected from the group consisting of isophthalic acid (IA) and terephthalic acid (TA). Isophthalic acid and terephthalic acid can be used alone or in combination. The phthalic acid is preferably terephthalic acid, optionally in combination with isophthalic acid.

Non limitative examples of aliphatic diamines are typically aliphatic alkylene diamines having 2 to 18 carbon atoms, which are advantageously selected from the group consisting of 1,2-diaminoethane, 1,2-diaminopropane, propylene-1,3-diamine, 1,3-diaminobutane, 1,4-diaminobutane, 1,5-diaminopentane, 1,4-diamino-1,1-dimethylbutane, 1,4-diamino-1-ethylbutane, 1,4-diamino-1,2-dimethylbutane, 1,4-diamino-1,3-dimethylbutane, 1,4-diamino-1,4-dimethylbutane, 1,4-diamino-2,3-dimethylbutane, 1,2-diamino-1-butylethane, 1,6-diaminohexane, 1,7-diaminoheptane, 1,8-diamino-octane, 1,6-diamino-2,5-dimethylhexane, 1,6-diamino-2,4-dimethylhexane, 1,6-diamino-3,3-dimethylhexane, 1,6-diamino-2,2-dimethylhexane, 1,9-diaminononane, 1,6-diamino-2,2,4-trimethylhexane, 1,6-diamino-2,4,4-trimethylhexane, 1,7-diamino-2,3-dimethylheptane, 1,7-diamino-2,4-dimethylheptane, 1,7-diamino-2,5-dimethylheptane, 1,7-diamino-2,2-dimethylheptane, 1,10-diaminodecane, 1.8-diamino-1,3-dimethyloctane, 1,8-diamino-1,4-dimethyloctane, 1.8-diamino-2,4-dimethyloctane, 1,8-diamino-3,4-dimethyloctane, 1.8-diamino-4,5-dimethyloctane, 1.8-diamino-2,2-dimethyloctane, 1.8-diamino-3,3-dimethyloctane, 1,8-diamino-4,4-dimethyloctane, 1,6-diamino-2,4-diethylhexane, 1,9-diamino-5-methylnonane, 1,11-diaminoundecane and 1,12-diaminododecane.

Also, the aliphatic diamine may be chosen from cycloaliphatic diamines such as isophorone diamine (also known as 5-amino-(1-aminomethyl)-1,3,3-trimethylcyclohexane), 1,3-cyclohexanebis(methylamine) (1,3-BAMC), 1,4-cyclohexanebis(methylamine) (1,4-BAMC), 4,4-diaminodicyclohexylmethane (PACM), and bis(4-amino-3-methylcyclohexyl)methane.

According to preferred embodiments of the present invention, the aliphatic diamine is preferably selected from the group consisting of 1,6-diaminohexane (also known as hexamethylene diamine), 1,9-diaminononane, 1,10-diaminodecane, 1,11-diaminoundecane and 1,12-diaminododecane.

Among aromatic diamines, mention can be notably made of meta-phenylene diamine (MPD), para-phenylene diamine (PPD), 3,4′-diaminodiphenyl ether (3,4′-ODA), 4,4′-diaminodiphenyl ether (4,4′-ODA), meta-xylylene diamine (MXDA), and para-xylylene diamine (PXDA).

According to preferred embodiments of the present invention, the aromatic diamine is preferably meta-xylylene diamine (MXDA).

In addition, aromatic amino carboxylic acids or derivatives thereof may also be used for the manufacture of the polyamide of the polymer composition (C), which is generally selected from the group consisting of 4-(aminomethyl)benzoic acid and 4-aminobenzoic acid, 6-aminohexanoic acid, 1-aza-2-cyclononanone, 1-aza-2-cyclododecanone, 11-aminoundecanoic acid, 12-aminododecanoic acid, 4-(aminomethyl)benzoic acid, cis-4-(aminomethyl)cyclohexanecarboxylic acid, trans-4-(aminomethyl)cyclohexanecarboxylic acid, cis-4-aminocyclohexanecarboxylic acid and trans-4-aminocyclohexanecarboxylic acid.

Non limitative examples of polyamides of the polymer composition (C) are: the polymer of adipic acid with meta-xylylene diamine (also known as PAMXD6 polymers, which are notably commercially available as IXEF® polyarylamides from Solvay Specialty Polymers U.S.A, L.L.C.), the polymers of phthalic acid, chosen among isophthalic acid (IA) and terephthalic acid (TA) and at least one aliphatic diamine such as 1,6-diaminohexane (notably commercially available as AMODEL® polyphthalamides from Solvay Specialty Polymers U.S.A, L.L.C.), the polymer of terephthalic acid with 1,9-nonamethylene diamine, the polymer of terephthalic acid with 1,10-decamethylene diamine, the polymer of terephthalic acid with dodecamethylene diamine, the polymer of 1,11-undecane diamine with terephthalic acid, the copolymer of terephthalic acid and isophthalic acid with hexamethylene diamine, the copolymer of terephthalic acid with hexamethylene diamine and decamethylene diamine; the copolymer of terephthalic acid and isophthalic acid with hexamethylene diamine and decamethylene diamine; the copolymer of terephthalic acid with decamethylene diamine and 11-amino-undecanoic acid, the copolymer of terephthalic acid with hexamethylene diamine and 11-amino-undecanoic acid; the copolymer of terephthalic acid with hexamethylene diamine and bis-1,4-aminomethylcyclohexane; the copolymer of terephthalic acid with hexamethylene diamine and bis-1,3-aminomethylcyclohexane; the copolymer of hexamethylene diamine with terephthalic acid and 2,6-napthalenedicarboxylic acid; the copolymer of hexamethylene diamine with terephthalic acid and sebacic acid; the copolymer of hexamethylene diamine with terephthalic acid and 1,12-diaminododecanoic acid; the copolymer of hexamethylene diamine with terephthalic acid, isophthalic acid and 1,4-cyclohexanedicarboxylic acid; the copolymer of decamethylene diamine with terephthalic acid and 4-aminocyclohexanecarboxylic acid; the copolymer of decamethylene diamine with terephthalic acid and 4-(aminomethyl)-cyclohexanecarboxylic acid; the polymer of decamethylene diamine with 2,6-napthalenedicarboxylic acid; the copolymer of 2,6-napthalenedicarboxylic acid with hexamethylene diamine and decamethylene diamine; the copolymer of 2,6-napthalenedicarboxylic acid with hexamethylene diamine and decamethylene diamine; the polymer of decamethylene diamine with 1,4-cyclohexanedicarboxylic acid, the copolymer of hexamethylene diamine with 11-amino-undecanoic acid and 2,6-napthalenedicarboxylic acid; the copolymer of terephthalic acid with hexamethylene diamine and 2-methylpentamethylene diamine; the copolymer of terephthalic acid with decamethylene diamine and 2-methylpentamethylene diamine; the copolymer of 2,6-napthalenedicarboxylic with hexamethylene diamine and 2-methylpentamethylene diamine; the copolymer of 1,4-cyclohexanedicarboxylic acid with decamethylene diamine and 2-methylpentamethylene diamine.

According to a first preferred embodiment of the invention, the polyamide is a polyphthalamide, i.e. a polyamide which comprises recurring units (R_{PPA}) which are derived from the polycondensation of at least one phthalic acid. The expression “phthalic acid” is used to refer to anyone of isophthalic acid, terephthalic acid and orthophthalic acid.

According to a second preferred embodiment of the invention, the polyamide is selected from the group consisting of the polymer of adipic acid with meta-xylylene diamine, the polymer of terephthalic acid with 1,9-nonamethylene diamine, the polymer of terephthalic acid with 1,10-decamethylene diamine, the copolymer of terephthalic acid and optionally isophthalic acid with hexamethylene diamine, the copolymer of terephthalic acid with hexamethylene diamine and decamethylene diamine and the copolymer of terephthalic acid and isophthalic acid with hexamethylene diamine and decamethylene diamine.

The melting point of the polyamide of the polymer composition (C) is preferably of at least 260° C., preferably at least 280° C., more preferably at least 300° C. and most preferably at least 310° C.

Excellent results were obtained when using polyamides polymers of phthalic acid, chosen among isophthalic acid (IA) and terephthalic acid (TA) and at least one aliphatic diamine such as 1,6-diaminohexane.

In certain embodiments, the polymer (P) is preferably a polyester. The term “polyester” is intended to include “copolyesters” and is understood to denote a polymer comprising at least 50 mol %, preferably at least 85 mol % of recurring units comprising at least one ester moiety (commonly described by the formula: —R—(C═O)—OR′—). Polyesters may be obtained by ring opening polymerization of at least one cyclic monomer (M_{A}) comprising at least one ester moiety; by polycondensation of at least one monomer (M_{B}) comprising at least one hydroxyl group and at least one carboxylic acid group, or by polycondensation of a mixture comprising at least one monomer (M_{C}) comprising at least two hydroxyl groups (a diol) and at least one monomer (M_{D}) comprising at least two carboxylic acid groups (a dicarboxylic acid. As used herein, the term dicarboxylic acid is intended to include dicarboxylic acids and any derivative of dicarboxylic acids, including their associated acid halides, esters, half-esters, salts, half-salts, anhydrides, mixed anhydrides, or mixtures thereof. The polyester comprises at least 50 mol %, preferably at least 60 mol %, more preferably at least 70 mol %, still more preferably at least 80 mol % and most preferably at least 90 mol % of recurring units comprising, in addition to the at least one ester moiety, at least one cycloaliphatic group. Excellent results were obtained when the polyester was essentially composed of recurring units comprising at least one ester moiety and at least one cycloaliphatic group. The cycloaliphatic group may derive from monomers (M_{A}), monomers (M_{B}), monomers (M_{C}) or monomers (M_{D}) comprising at least one group which is both aliphatic and cyclic.

Non limitative examples of monomers (M_{A}) include lactide and caprolactone.

Non limitative examples of monomers (M_{B}) include glycolic acid, 4-hydroxybenzoic acid and 6-hydroxynaphthalene-2-carboxylic acid.

Non limitative examples of monomers (M_{C}) include 1,4-cyclohexanedimethanol, ethylene glycol, 1,2-propanediol, 1,3-propanediol, 1,4-butanediol, 1,5-pentanediol, 1,6-hexanediol, 1,8-octanediol, 1,10-decanediol, 2,2,4-trimethyl 1,3-pentanediol, 2,2,4,4-tetramethyl-1,3-cyclobutanediol, and neopentyl glycol, while 1,4-cyclohexanedimethanol and neopentyl glycol are preferred.

Non limitative examples of monomers (M_{D}) include terephthalic acid, isophthalic acid, naphthalene dicarboxylic acids, 1,4-cyclohexane dicarboxylic acid, succinic acid, sebacic acid, and adipic acid, while terephthalic acid and 1,4-cyclohexane dicarboxylic acid are preferred.

When the polyester is a copolymer, monomers (M_{C}) and (M_{D}) are preferably used. In such a case, monomer (M_{C}) is preferably 1,4-cyclohexanedimethanol and monomer (M_{D}) is preferably a mixture of terephthalic acid and 1,6-naphthalene dicarboxylic acid.

When the polyester is a homopolymer, it may be selected from poly(cyclohexylenedimethylene terephthalate) (“PCT”) and poly(cyclohexylenedimethylene naphthalate) (“PCN”). Most preferably, it is PCT (i.e. a homopolymer obtained through the polycondensation of terephthalic acid with 1,4-cyclohexylenedimethanol).

The polyester has advantageously an intrinsic viscosity of from about 0.4 to about 2.0 dl/g as measured in a 60:40 phenol/tetrachloroethane mixture or similar solvent at about 30° C. Particularly suitable polyester (P) for this invention has an intrinsic viscosity of 0.5 to 1.4 dl/g.

The polyester has a melting point, as measured by DSC according to ISO-11357-3, of advantageously at least 250° C., preferably at least 260° C., more preferably at least 270° C. and most preferably at least 280° C. Besides, its melting point is advantageously of at most 350° C., preferably at most 340° C., more preferably at most 330° C. and most preferably at most 320° C. Excellent results were obtained with a polyester (P) having a melting point ranging from 280° C. to 320° C.

The polyester is preferably present in an amount of at least 40 wt. %, more preferably at least 45 wt. %, still more preferably at least 47 wt. %, and most preferably at least 48 wt. %, based on the total weight of the polymer composition (C). The polyester is also present in an amount of advantageously at most 80 wt. %, preferably at most 75 wt. %, more preferably at most 70 wt. %, still more preferably at most 65 wt. %, and most preferably at most 60 wt. %, based on the total weight of the polymer composition (C). Excellent results were obtained when the polyester was present in the polymer composition (C) in an amount from about 45 to about 60 wt. %, preferably from about 48 to about 58 wt. %, based on the total weight of the polymer composition (C).

In certain other embodiments, the polymer (P) is preferably an epoxy resin. Epoxy resins are generally compounds with terminal, and/or internal incorporated epoxy groups. The term “epoxy resin” is intended to denote resin having advantageously at least two epoxy groups, preferably two to six epoxy groups. The epoxy compounds having 2 to 4 epoxy groups are particularly preferred. Said epoxy compounds may be in any solid, semi-solid or liquid form.

The terms of epoxy (or epoxide), 1,2-epoxy (or epoxide), vicinal epoxy (or epoxide) and oxirane group are also art recognized terms for this epoxy group.

Suitable epoxy resins may be saturated, unsaturated, cycloaliphatic, alicyclic or heterocyclic. Particularly suitable epoxy compounds are for example based on reaction products of polyfunctional alcohols, phenols, cycloaliphatic carboxylic acids, aromatic amines, or aminophenols with epichlorohydrin, or else cycloaliphatic epoxides or cycloaliphatic epoxyesters. It is also possible to use a mixture of various epoxy resins.

Specifically, among the epoxy resins that may be suitable for the purposes of this invention are resorcinol diglycidyl ether; diglycidyl ether of bisphenol A (or 2,2-bis[p-(2,3-epoxy-propoxy)phenyl]-propane), diglycidyl ether of bromobisphenol A (or 2,2-bis[4-(2,3-epoxypropoxy)3-bromo-phenyl]propane; diglycidylether of bisphenol F (or 2,2-bis[p-(2,3-epoxypropoxy)phenyl]methane), triglycidyl ether of p-aminophenol (or 4-(2,3-epoxypropoxy)-N,N-bis(2,3-epoxy-propyl)aniline), triglycidyl ether of meta-aminophenol (or 3-(2,3-epoxypropoxy)N,N-bis(2,3-epoxypropyl)aniline); triglycidylether of tris(4-hydroxyphenyl)methane, tetraglycidyl methylene dianiline (or N,N,N′-tetra-tetra(2,3-epoxypropyl)4,4′-diamino-diphenyl methane), tetraglycidyl ether of tetra(4-hydroxy phenyl)ethane, polyglycidyl ethers of phenol-formaldehyde novalac, polyglycidyl ether of orthocresol-novalac, polyglycidyl ethers of polymeric novalacs, cycloaliphatic epoxides and epoxide esters and any combination thereof. More preferably, compound E is choosen among triglycidyl ether of p-aminophenol(or 4-(2,3-epoxypropoxy)-N,N-bis(2,3-epoxy-propyl)aniline), triglycidyl ether of meta-aminophenol (or 3-(2,3-epoxypropoxy)N,N-bis(2,3-epoxypropyl)aniline)and triglycidylether of tris(4-hydroxyphenyl)methane. Particular preferred epoxy resin is triglycidyl ether of para-aminophenol.

The epoxy resin is generally present in the polymer composition (C) in an amount of at least 30 wt. %, preferably of at least 40 wt. %, more preferably of at least 50 wt. %, and most preferably of at least 60 wt. %, based on the total weight of the composition (C). It is further understood that the wt. % of the epoxy resin in the polymer composition (C) will generally be of at most 90 wt. %, preferably of at most 80 wt. %, more preferably of at most 75 and most preferably of at most 70 wt. %, based on the total weight of the composition (C).

Excellent results were obtained when the polymer composition (C) comprised the epoxy resin in an amount of 30-90 wt. %, preferably of 40-80 wt. %, more preferably from 50-70 wt. % based on the total weight of the composition (C).

In certain other embodiments, the polymer (P) is preferably a silicon resin. The term “silicon resin” is intended to denote polymers more than 50 mol % of the recurring units of which contain silicon, carbon, hydrogen and oxygen, such as the one depicted below

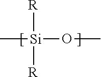

where R′s are equal or different from each other and chosen from alkyl groups.

The silicone resin may be prepared by any general method. Typically, silicone resins are formed by hydrolytic condensation of various silicone precursors. Some starting materials used in the formation of silicone resins include but are not limited to sodium silicate, chlorosilane, tetraethoxysilane, ethyl polysilicate, dimethyldichlorosilane and disiloxanes. However, the silicon resin if the polymer composition (C) is not limited to a type of silicone material which is formed by branched, cage-like oligosiloxanes with the general formula of RₙSiXₘO_{y}, where R is a non-reactive substituent, e.g., methyl or phenyl group, and X is a functional group, e.g., hydrogen, hydroxyl, chlorine or alkoxy group. The foregoing groups may be highly crosslinked to form insoluble polysiloxane structures. Moreover, when R is a methyl group, four possible functional siloxane monomeric units include but are not limited to Me₃SiO, Me₂SiO₂, MeSiO₃ and SiO₄. Silicone resins also include silicone rubbers which are rubber-like material composed of silicone which is vulcanized through the introduction of heat. The vulcanization process may include more than one stage, e.g., heating to form a shape followed by a prolonged post-curing process. Silicone rubber can be colored and may further be extruded into tubes, strips, cords, etc., and such applications may be further used to form gaskets and o-rings. Some silicone polymers are formed by combining two or more components thereby resulting in a composition that may be crosslinked, cured or vulcanized. For example, a silicone polymer may be formed from first and second silicone materials. The first silicone material may be an alkyl silicone polymer, e.g., methyl silicone, and the second silicone material may be a vinyl silicone polymer. The combination of the first and second silicone polymers is heat curable which may be accelerated with a catalyst such as platinum.

The wt. % of the silicon resin in the polymer composition (C) is generally of at least 30 wt. %, preferably of at least 40 wt. %, more preferably of at least 50 wt. %, and most preferably of at least 60 wt. %, based on the total weight of the composition (C). It is further understood that the wt. % of the silicon resin in the polymer composition (C) will generally be of at most 90 wt. %, preferably of at most 80 wt. %, more preferably of at most 75 and most preferably of at most 70 wt. %, based on the total weight of the composition (C).

### The Flame Retardant System

The polymer composition (C) of the present invention comprises from 5 to 40 wt. %, based on the total weight of the composition (C) of a flame retardant system. The flame retardant system may notably comprise at least one flame retardant selected from the group consisting of halogenated flame retardants and halogen free flame retardants.

Halogenated flame retardants of various polymer compositions are well known in the art. They can be any halogenated compound that can provide flame retardant properties to the polymer compositions. They typically include chlorinated and/or brominated compounds and polymers.

Notable halogenated flame retardants available on the market include but are not limited to 1,2-bis(tribromophenoxy)ethane, brominated epoxy oligomers, brominated polystyrene, chlorendic anhydride, chlorinated paraffins, decabromobiphenyl, decabromodiphenylethane, decabromodiphenyloxide, dechlorane plus, dibromoneopentylglycol, ethylene-bis(5,6-dibromonorbornane-2,30dicarboximide), ethylene-bis(tetrabromophthalimide), halogenated polyetherpolyols, hexabromocyclododecane, octabromodiphenyloxide, octabromotrimethylphenylindane, pentabromodiphenyloxide, poly(dibromostyrene), poly(pentabromobenzylacrylate), tetrabromo-bisphenol-A, tetrabromo-bisphenol-A, bis(2,3-dibromopropyl ether), tetrabromophthalate diols and tetrabromophthalic anhydride.

Preferably, the halogenated flame retardant is a brominated or chlorinated compound/polymer, more preferably a brominated compound/polymer, even more preferably a brominated compound/polymer with a bromine content of 50-70 weight %, relative to the weight of the brominated compound. Even more preferably, the halogenated flame retardant is a halogenated polystyrene or halogenated polyphenylene ether. Most preferably, the halogenated flame retardant compound is a brominated polystyrene, still more preferably a polybromostyrene.

The polymer composition (C) may also comprise, in addition to the halogenated flame retardant system, a flame retardant synergist (FRS-A). The flame retardant synergist (FRS-A) may comprise antimony trioxide, antimony dioxide, sodium antimonate, iron oxide, zinc phosphate and/or a metal salt of boric acid or stannic acid, wherein said metal is selected from the group consisting of zinc, an alkali metal (metal of group I of the Periodic Table) and an alkaline earth metal (metal of group II of the Periodic Table). Suitable metal salts of stannic acid include, for example, zinc stannate, zinc hydroxystannate, magnesium stannate, sodium stannate and potassium stannate. Suitable metal salts of boric acid include, for example, zinc borate, calcium borate and magnesium borate. Of these metal salts, zinc borate and zinc stannate, and mixtures thereof are preferred. More preferably, polymer composition (C) comprises sodium antimonate and/or zinc borate. The advantage of these preferred embodiments is that the color stability after retention at elevated temperature is even further enhanced.

When present, the flame retardant synergist (FRS-A) is preferably present in an amount of 0.1-20 wt. %, more preferably 1-15 wt. %, still more preferably 5-10 wt. %, relative to the total weight of the polymer composition (C).

Halogen free flame retardants may also be present in the polymer composition (C) and are well known in the art. As halogen free flame retardants, the polymer composition (C) may notably comprise at least one organophosphorous compound selected from the group consisting of phosphinic salts (phosphinates), diphosphinic salts (diphosphinates) and condensation products thereof. Preferably, the organophosphorous compound is selected from the group consisting of phosphinic salt (phosphinate) of the formula (I), a diphosphinic salt (diphosphinate) of the formula (II) and condensation products thereof:

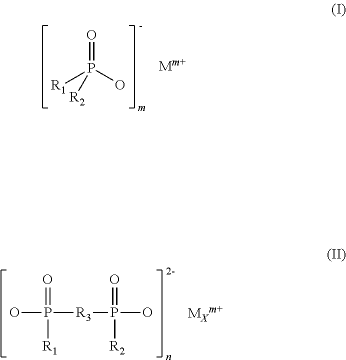

wherein: R₁, R₂ are identical or different and each of R₁ and R₂ is a hydrogen or a linear or branched C1-C6 alkyl group or an aryl group; R₃ is a linear or branched C1-C10 alkylene group, a C6-C10 arylene group, an alkyl-arylene group, or an aryl-alkylene group; M is selected from calcium ions, magnesium ions, aluminum ions, zinc ions, titanium ions, and combinations thereof; m is an integer of 2 or 3; n is an integer of 1 or 3; and x is an integer of 1 or 2.

Preferably, R₁ and R₂ are independently selected from methyl, ethyl, n-propyl, isopropyl, n-butyl, tert-butyl, n-pentyl, and phenyl; R₃ is selected from methylene, ethylene, n-propylene, isopropylene, n-butylene, tert-butylene, n-pentylene, n-octylene, n-dodecylene, phenylene, naphthylene, methylphenylene, ethylphenylene, tert-butylphenylene, methylnaphthylene, ethylnaphthylene, tert-butylnaphthylene, phenylmethylene, phenylethylene, phenylpropylene, and phenylbutylene; and M is selected from aluminum and zinc ions.

Phosphinates are preferred as organophosphorous compound. Suitable phosphinates have been described in U.S. Pat. No. 6,365,071. Particularly preferred phosphinates are aluminum phosphinates, calcium phosphinates, and zinc phosphinates. Excellent results were obtained with aluminum phosphinates. Among aluminum phosphinates, aluminium ethylmethylphosphinate and aluminium diethylphosphinate and combinations thereof are preferred. Excellent results were in particular obtained when aluminium diethylphosphinate was used.

The polymer composition (C) may also comprise, in addition to the halogen free flame retardant, a flame retardant synergist (FRS-B), preferably nitrogen-containing synergists. Indeed, synergistic combinations of phosphinates with nitrogen-containing compounds, known to have more effective action than the phosphinates alone in many polymers (see e.g. U.S. Pat. No. 6,365,071, U.S. Pat. No. 6,207,736, U.S. Pat. No. 6,509,401) are also in accordance with the invention.

The nitrogen-containing synergists preferably comprise benzoguanamine, tris(hydroxyethyl) isocyanurate, allantoin, glycoluril, melamine, melamine cyanurate, dicyandiamide, guanidine, carbodiimides, and condensation products thereof. The nitrogen-containing synergists preferably comprise condensation products of melamine. By way of example, condensation products of melamine are melem, melam, or melon, or compounds of this type with a higher condensation level, or else a mixture of the same, and, by way of example, may be prepared by the process described in U.S. Pat. No. 5,985,960.

The phosphorus/nitrogen-containing synergists may comprise reaction products of melamine with phosphoric acid or with condensed phosphoric acids, or comprise reaction products of condensation products of melamine with phosphoric acid or condensed phosphoric acids, or else comprise a mixture of the specified products.

The reaction products of melamine with phosphoric acid or with condensed phosphoric acids are compounds which arise via reaction of melamine or of the condensed melamine compounds, such as melam, melem, or melon etc., with phosphoric acid. By way of example, these are dimelamine phosphate, dimelamine pyrophosphate, melamine phosphate, melamine pyrophosphate, melamine polyphosphate, melam polyphosphate, melon polyphosphate, and melem polyphosphate, and mixed polysalts, e.g. those described in U.S. Pat. No. 6,121,445 and U.S. Pat. No. 6,136,973.

In a separate embodiment, the phosphorus/nitrogen-containing synergist may also be ammonium hydrogenophosphate, ammonium dihydrogenophosphate, or ammonium polyphosphate.

When present, the flame retardant synergist (FRS-B) is preferably present in an amount of 0.1-10 wt. %, more preferably 0.5-8 wt. %, still more preferably 1-5 wt. %, relative to the total weight of the polymer composition (C).

The polymer composition (C) of the present invention comprises from 5 to 30 wt. % of a flame retardant system, based on the total weight of the polymer composition (C). The flame retardant system is present in the total weight of the polymer composition (C) in an amount of preferably at least 8 wt. %, more preferably of at least 10 wt. %, still more preferably of at least 12 wt. % and most preferably of at least 13 wt. %. Besides, the wt. % of the flame retardant system in the total weight of the polymer composition (C) is preferably of at most 25 wt. %, more preferably of at most 23 wt. %, still more preferably of at most 20 wt. % and most preferably of at most 18 wt. %.

### Magnesium Oxide

As mentioned above, the polymer composition (C) of the present invention comprises from 1 to 7 wt. %, based on the total weight of the composition (C) of magnesium oxide.

The magnesium oxide is present in the total weight of the polymer composition (C) in an amount of preferably at least 2, more preferably of at least 2.5, still more preferably of at least 2.75 and most preferably of at least 3 wt. %. Besides, the magnesium oxide is present in the total weight of the polymer composition (C) in an amount of preferably at most 6, more preferably of at most 5.5, still more preferably of at most 5 and most preferably of at most 4.5 wt. %. Excellent results were obtained when the magnesium oxide was present in the total weight of the polymer composition (C) in an amount of from 3 to 5 wt. %.

### Other Optional Ingredients

The polymer composition (C) may also comprise at least one white pigment. The white pigment is preferably selected from the group consisting of TiO₂, ZnS₂ and BaSO₄.

The shape of the particles is not particularly limited; they may be notably round, flaky, flat, and so on.

The white pigment is preferably titanium dioxide (TiO₂). The form of titanium dioxide is not particularly limited and a variety of crystalline forms such as the anatase form, the rutile form, and the monoclinic type can be used. However, the rutile form is preferred due to its higher refraction index and its superior light stability. Titanium dioxide may or may not be treated with a surface treatment agent. Preferably the weight-average particle size of the titanium oxide is in the range of 0.15 μm to 0.35 μm.

The surface of the titanium dioxide particles will preferably be coated. The titanium dioxide will preferably be first coated with an inorganic coating and then with an organic coating. The titanium dioxide particles may be coated using any method known in the art. Preferred inorganic coatings include metal oxides. Organic coatings may include one or more of carboxylic acids, polyols, alkanolamines, and/or silicon compounds.

The white pigment is preferably present in an amount of at least 1 wt. %, preferably of at least 6 wt. %, more preferably of at least 8 wt. %, even more preferably of at least 10 wt. %, and most preferably of at least 15 wt. %, based on the total weight of the polymer composition (C). Besides, the white pigment is also preferably present in an amount of at most 50 wt. %, preferably of at most 45 wt. %, more preferably of at most 40 wt. %, even more preferably of at most 35 wt. %, and most preferably of at most 30 wt. %, based on the total weight of the polymer composition (C).

Excellent results were obtained when titanium dioxide was used in an amount of 10-40 wt. %, preferably of 15-35 wt. %, based on the total weight of the polymer composition (C).

The polymer composition (C) may also comprise other polymers than the above mentioned polymers (P) such as polycarbonate, polyethylene glycol, polysulfone, PEEK and PTFE.

The polymer composition (C) may also further comprise at least one reinforcing filler. Reinforcing fillers are preferably fibrous. More preferably, the reinforcing filler is selected from glass fiber, carbon fiber, synthetic polymeric fiber, aramid fiber, aluminum fiber, titanium fiber, magnesium fiber, boron carbide fibers, rock wool fiber, steel fiber, wollastonite, etc. Still more preferably, it is selected from glass fiber and wollastonite.

A particular class of fibrous fillers consists of whiskers, i.e. single crystal fibers made from various raw materials such as SiC, BC, Fe and Ni. Among fibrous fillers, glass fibers are preferred; they include chopped strand A-, E-, C-, D-, S- T- and R-glass fibers, as described in chapter 5.2.3, p. 43-48 of Additives for Plastics Handbook, 2nd ed., John Murphy.

Excellent results were obtained when wollastonite and/or glass fibers were used. Glass fibers may have a round cross-section or an elliptic cross-section (also called flat fibers).

If present, the reinforcing filler is preferably present in an amount of at least 2 wt. %, more preferably at least 4 wt. %, still more preferably at least 5 wt. %, and most preferably at least 10 wt. %, based on the total weight of the polymer composition (C). When present, the reinforcing filler is also preferably present in an amount of at most 40 wt. %, more preferably at most 30 wt. %, still more preferably at most 25 wt. %, and most preferably at most 20 wt. %, based on the total weight of the polymer composition (C).

Excellent results were obtained when the reinforcing filler was present in the composition in an amount from about 5 to about 40 wt. %, preferably from about 5 to about 25 wt. %, and more preferably from about 10 to about 20 wt. %, based on the total weight of the polymer composition (C).

The polymer composition (C) can further contain one or more impact modifiers. The impact modifiers can be reactive with the polymer (P) or non-reactive. In certain specific embodiment, the polymer composition (C) contains at least one reactive impact modifier and at least one non-reactive impact modifier.

Reactive impact modifiers that may be used include ethylene-maleic anhydride copolymers, ethylene-alkyl(meth)acrylate-maleic anhydride copolymers, ethylene-alkyl(meth)acrylate-glycidyl(meth)acrylate copolymers, and the like. An example of such reactive impact modifier is a random terpolymer of ethylene, methylacrylate and glycidyl methacrylate.

Non-reactive impact modifiers that may be blended into the polymer composition (C) generally include various rubber materials, such as acrylic rubbers, ASA rubbers, diene rubbers, organosiloxane rubbers, EPDM rubbers, SBS or SEBS rubbers, ABS rubbers, NBS rubbers and the like. Particular examples of non-reactive impact modifiers include ethyl butylacrylate, ethyl(methyl)acrylate or 2 ethyl hexyl acrylate copolymers.

If present, the impact modifier is preferably present in an amount of at least 2 wt. %, more preferably at least 4 wt. %, still more preferably at least 5 wt. %, and most preferably at least 10 wt. %, based on the total weight of the polymer composition (C). When present, the impact modifier is also preferably present in an amount of at most 20 wt. %, more preferably at most 15 wt. %, still more preferably at most 10 wt. %, and most preferably at most 5 wt. %, based on the total weight of the polymer composition (C).

The polymer composition (C) may optionally further contain up to about 3 wt. % of ultraviolet light stabilizers or UV blockers, based on the total weight of the polymer composition (C). Examples include triazoles and triazines, oxanilides, hydroxybenzophenones, benzoates, and α-cyanoacrylates. When present, the ultraviolet light stabilizers are preferably present in an amount of about 0.1 to about 3 wt. %, or preferably about 0.1 to about 1 wt. %, or more preferably about 0.1 to about 0.6 wt. %, of the total weight of the polymer composition (C).

The polymer composition (C) may also comprise other optional ingredients such as mold release agents, lubricants, nucleating agents, plasticizers, optical brighteners and other stabilizers, different from the ones described above.

In particular, the polymer composition (C) may comprise talc as a nucleating agent. When present, the talc is preferably present in an amount of about 0.5 to about 3 wt. %, or preferably about 0.8 to about 1.2 wt. %, or more preferably about 1 wt. %, of the total weight of the polymer composition (C).

Any melt-mixing method may be used to combine the polymeric components and non-polymeric ingredients to prepare the polymer composition (C). For example, the polymeric components and non-polymeric ingredients may be added to a melt mixer, such as, for example, a single or twin-screw extruder, a blender or a Banbury mixer, either all at once through a single step addition, or in a stepwise fashion, and then melt-mixed. When adding the polymeric components and non-polymeric ingredients in a stepwise fashion, part of the polymeric components and/or non-polymeric ingredients are first added and melt-mixed with the remaining polymeric components and non-polymeric ingredients are subsequently added and further melt-mixed until a well-mixed composition is obtained.

As used herein, the terms “light emitting diode device” and “LED device” intend to denote a device comprising at least one light emitting diode, an electrical connection capable of connecting the diode to an electrical circuit, and a housing partially surrounding the diode. The LED device may optionally have a lens that fully or partially covers the LED.

LEDs are preferably chosen from the group of top view LEDs, side view LEDs and power LEDs. The top view LEDs are notably used in automotive lighting applications such as panel displays, stop lights and turn signals. The side view LEDs are notably used for mobile appliance applications such as, for example, cell phones and PDAs. The power LEDs are notably used in flashlights, automotive day light running lights, signs and as backlight for LCD displays and TVs.

The part of LED device according to the present invention may be incorporated into LED devices used in applications such as traffic signals, large area displays, video screens, interior and exterior lighting, cellular telephone display backlights, automotive displays, vehicle brake lights, vehicle head lamps, laptop computer display backlights, pedestrian floor illumination and flashlights.

The articles of the present invention are preferably parts of LED devices such as housings, reflectors and heatsinks.

The part of LED device comprising the polymer composition (C) may be manufactured by any suitable method known to those skilled in the art for melt-processing composition (C), such as injection molding or the like.

The part of LED device of the invention may be overmolded over a metal (such as copper or silver-coated copper) lead frame that can be used to make an electrical connection to a LED inserted into the housing. The part of LED device of the invention preferably has a cavity in the portion of the housing that surrounds the LED, which serves to reflect the LED light in the outward direction and towards a lens, if one is present. The cavity may be in a cylindrical, conical, parabolic or other curved form, and preferably has a smooth surface. Alternatively, the walls of the cavity may be parallel or substantially parallel to the diode. A lens may be formed over the diode cavity and may comprise an epoxy or silicone material.

Preferably at least 50 wt. % and more preferably more than 80 wt. % of the part comprises the polymer composition (C) (the part can possibly further contain notably a metal; for example, for certain end uses, the surface of the part acting as reflector may be metal plated). More preferably, more than 90 wt. % of the part comprises the polymer composition (C). Still more preferably, the part consists essentially of the polymer composition (C). The most preferably, the part consists of the polymer composition (C).

Should the disclosure of any patents, patent applications, and publications which are incorporated herein by reference conflict with the description of the present application to the extent that it may render a term unclear, the present description shall take precedence.

### EXAMPLES

The disclosure will now be illustrated with working examples, which are intended to illustrate the present invention and are not intended to restrictively imply any limitations on the scope of the present disclosure.

The following commercially available materials were used: Polyamide: AMODEL® polyphthalamide A-9009 from Solvay Specialty Polymers USA, L.L.C.
Glass fiber: OCV 995 from OCV™ Reinforcements.
Titanium Dioxide: TIPAQUE® PC-3 available from Ishihara Sangyo Kaisha, Ltd.
Magnesium oxide: KYOWAMAG MF-150 available from Kyowa Chemical Industry Co Ltd.
Halogen free flame retardant: EXOLIT® OP1230 FR from Clariant Corp, which is an organic phosphinate.
Halogenated flame retardant package: The four following ingredients were used in the ratio 82.25/13.55/1.30/2.90, PDBS 80 from Chemtura (homopolymer of dibromostyrene), Pyroblock SAP-2 from Chemtura (sodium antimonate synergist), calcium oxide CA602 from Atlantic Equipment Engineers and Primacor 1410 from Entec Polymers LLC which is an ethylene acrylic acid copolymer.
Hindered amine: NYLOSTAB® SEED stabilizer is a hindered amine commercially available from Clariant Corp.
Antioxidant: ADK AO-80 from Amfine Chemical Corporation is a hindered phenolic antioxidant
Talc: Imi-Fabi HTP-4 available from Imi Fabi L.L.C.
LLDPE: LLDPE GRSN-9820 NT 7 commercially available from DOW.

### General Procedure for the Preparation of the Compositions

The polyamide resin described above was fed to the first barrel of a ZSK-26 twin screw extruder comprising 12 zones via a loss in weight feeder. The barrel set-point temperatures were in the range of 240-330° C. and the resins were melted before zone 5. The other ingredients were fed at zone 5 through a side stuffer via a loss in weight feeder. The screw rate was 175 rpm. The extrudates were cooled and pelletized using conventional equipment. The nature and quantity of the various ingredients used are summarized in Table 1, indicating the amount of each ingredient in wt. %.

TABLE 1
Nature and quantity of the ingredients used

| | E1 | CE2 | E3 | CE4 |
|---|---|---|---|---|
| Polyamide | 46.3 | 50.3 | 43.3 | 42.3 |
| Glass fiber | 20.0 | 20.0 | 5.0 | 10.0 |
| Titanium Dioxide | 18.0 | 18.0 | 15.0 | 15.0 |
| Antioxidant | 0.2 | 0.2 | 0.2 | 0.2 |
| Talc | 1.0 | 1.0 | 1.0 | 1.0 |
| Hindered amine | 0.2 | 0.2 | 0.2 | 0.2 |
| LLDPE | 0.3 | 0.3 | 0.3 | 0.3 |
| Magnesium oxide | 4.0 | 0.0 | 4.0 | 0.0 |
| Halogen free flame retardant | 10.0 | 10.0 | 0.0 | 0.0 |
| Halogenated flame retardant package | 0.0 | 0.0 | 28.0 | 28.0 |

### Reflectance Measurements

Behaviour of a part made from the exemplified compositions in a LED device has been simulated by exposing samples to high temperature. Therefore, each one of the compositions of example E-1, CE-2, E-3 and E-4 were used to prepare discs of about 50 mm diameter with a thickness of about 1.6 mm. Discs were placed in an oven at 260° C. for 10 minutes. Reflectance was measured with BKY-Gardner photo-spectrometer. The reflectivity results on the discs as molded and on discs after exposure high heat are summarized in Table 2, as well as the percentages of retention of reflectivity at a wavelength of 460 nm.

### Flame Resistance Measurements

A 20 mm vertical burning test was carried out according to UL Standard 94 which identifies test methods for flammability of plastic materials for parts in devices and appliances. A set of 5-0.79 mm thick—plastic specimens molded from compositions E-1, CE-2, E-3 and CE-4 were subjected to a 20 mm flame in accordance with the prescribed test procedures. The blue flame was applied centrally to the middle point of the bottom edge of the specimens for three seconds. The flame was then withdrawn and the afterflamme time (t₁) was measured. The procedure was repeated and the afterflamme time (t₂) was also measured. The sum of all afterflamme times were added up and also reported in Table 2.

TABLE 2
Reflectivity and flame resistance measurements results

| | E-1 | CE-2 | E-3 | CE-4 |
|---|---|---|---|---|
| Reflectivity measurements | | | | |
| As molded | 92.9 | 91.1 | 85.2 | 89.5 |
| After 10 min at 260° C. | 60.5 | 31.5 | 75.3 | 69.7 |
| Reflectivity retention (%) | 65.1 | 34.5 | 88.4 | 77.9 |
| Flame resistance measurements | | | | |
| Total afterflamme times | 115 | 225 | 11 | 53 |
| (t₁ + t₂) for the 5 specimens (s) | | | | |

### Results

The composition according to the present invention E-1 and E-3 surprisingly show higher retention of reflectivity as molded and after exposure to high heat compared to comparative examples CE-2, and CE-4, while at the same time featuring exceptional flame resistance.

The data summarized in Table 2 well demonstrate the synergy observed between the magnesium oxide and the flame retardant system. The compositions according to the present invention achieve outstanding optical properties both on the molded article as such and the same article having been submitted to thermal treatment, which is intended to mimic conditions to which the materials might be exposed during the manufacture of LED devices. The compositions according to the present invention achieve also excellent flame resistance, showing reduced afterflamme times when compared to the same compositions not comprising magnesium oxide (CE-2 and CE-4).

Comparative examples CE-2 and CE-4 provide thus evidence that the flame retardant system alone is not enough in providing the outstanding optical properties obtained with the examples according to the invention.

Example E-3, which combines both a halogenated flame retardant system and magnesium oxide, achieves unexpected results in terms of retention of reflectivity after high heat exposure and very low total afterflamme times.

Examples E-1 and E-3 according to the present invention comply thus with a wide set of requirements as set forth previously (notably good processability, high dimensional stability, high mechanical strength) and also surprisingly features a good reflectance after high heat treatment. Those compositions are therefore excellent candidates for the manufacture of LED components.

1-14. (canceled)

15. A part of a Light Emitting Diode device comprising a polymer composition (C) comprising:
at least one polymer (P) selected from the group consisting of a polyamide, a polyester, an epoxy and a silicon resin;
from 5 to 40 wt. %, based on the total weight of the composition (C), of a flame retardant system; and
from 1 to 7 wt. %, based on the total weight of the composition (C), of magnesium oxide.

16. The part according to claim 15 comprising from 3 to 5 wt. % of the magnesium oxide.

17. The part according to claim 15, wherein the polymer (P) is a polyamide.

18. The part according to claim 17, wherein the polyamide is a polyphthalamide.

19. The part according to claim 15, wherein the polymer (P) is a polyester.

20. The part according to claim 19, wherein the polyester is poly(cyclohexylenedimethylene terephthalate).

21. The part according to claim 15, wherein the polymer composition (C) further comprises at least a flame retardant synergist.

22. The part according to claim 15, wherein the polymer composition (C) further comprises at least one white pigment.

23. The part according to claim 15, wherein the polymer composition (C) further comprises at least one reinforcing filler.

24. The part according to claim 23, wherein the reinforcing filler is wollastonite, glass fibers, or mixtures thereof.

25. The part according to claim 15, wherein the flame retardant system comprises a halogenated flame retardant.

26. The part according to claim 25, wherein the halogenated flame retardant is a brominated compound/polymer.

27. The part according to claim 15, wherein the flame retardant system comprises a halogen free flame retardant.

28. The part according to claim 27, wherein the halogen free flame retardant comprises at least one organophosphorous compound selected from the group consisting of phosphinic salts (phosphinates), diphosphinic salts (diphosphinates), and condensation products thereof.
